(19) United States
(12) Patent Application Publication
(10) Pub. No.: US 2017/0005208 A1
(43) Pub. Date: Jan. 5, 2017

(54) SOLAR CELL

(71) Applicant: Panasonic Intellectual Property Management Co., Ltd., Osaka (JP)

(72) Inventors: Kenta MATSUYAMA, Osaka (JP); Hirotada INOUE, Hyogo (JP); Yasuko HIRAYAMA, Osaka (JP)

(21) Appl. No.: 15/264,798

(22) Filed: Sep. 14, 2016

Related U.S. Application Data
(63) Continuation of application No. 14/691,990, filed on Apr. 21, 2015.
Application No. 14/691,990 is a continuation of application No. PCT/JP2012/077346, filed on Oct. 23, 2012.

(51) Int. Cl. H01L 31/0236; H01L 31/0224; H01L 31/18; H01L 31/20; H01L 31/0376

(52) U.S. Cl. CPC H01L 31/02363; H01L 31/202; H01L 31/03762; H01L 31/1884; H01L 31/022441

(57) ABSTRACT

A method for manufacturing a solar cell may include forming a textured structure including multiple convex parts by etching a crystalline silicon substrate with etching liquid and forming an amorphous silicon layer on the crystalline silicon substrate with the textured structure formed thereon, by chemical vapor deposition or sputtering. An alkaline solution including at least one of a solution of sodium hydroxide and a solution of potassium hydroxide, additive including at least one of 4-propylbenzoic acid, 4-t-butylbenzoic acid, 4-n-butylbenzoic acid, 4-pentylbenzoic acid, 4-butoxybenzonic acid, 4-n-octylbenzenesulfonic acid, caprylic acid, and lauric acid may be added to the etching liquid. The textured structure may a chamfered section between main sloped surfaces of the convex parts, and a sharp trough part which is sandwiched by adjacent multiple convex parts.

### CROSS REFERENCE TO RELATED APPLICATIONS

This application is a continuation under 35 U.S.C. §120 of U.S. application Ser. No. 14/691,990, filed Apr. 21, 2015, the content of which is incorporated herein by reference. U.S. application Ser. No. 14/691,990 is a continuation application under 35 U.S.C. §120 of International Application No. PCT/JP2012/077346, filed Oct. 23, 2012, which is also incorporated herein by reference.

### TECHNICAL FIELD

The present invention relates to a solar cell.

### BACKGROUND ART

Patent Document 1 discloses a solar cell including a semiconductor substrate upon which there is formed a textured structure that is a finely uneven surface structure, in order to reduce reflection of light.

### CITATION LIST

### Patent Literature

### Patent Document 1

International Publication No. WO98/43304

### SUMMARY OF INVENTION

### Technical Problem

The shape of a textured structure may have an influence on breaking or cracking of a semiconductor substrate. Improvement of the shape of a textured structure is demanded for providing a damage-resistant solar cell.

### Solution to Problem

A solar cell of the present invention is provided with a semiconductor substrate, on a surface of which is formed a textured structure that includes multiple convex parts. The textured structure has chamfered sections between respective main sloped surfaces of convex parts and sharp trough parts sandwiched by adjacent multiple convex parts.

### Advantageous Effect of Invention

The present invention provides a damage-resistant solar cell.

### BRIEF DESCRIPTION OF DRAWINGS

FIG. 1 is a plan view of a solar cell serving as an example of an embodiment of the present invention, as viewed from a light-receiving surface side.

FIG. 2 is a partial sectional view taken along line A-A in FIG. 1.

FIG. 3 is an enlarged view of a trough part of a textured structure in FIG. 2.

FIG. 4 is an enlarged view of a front end of the textured structure in FIG. 2.

FIG. 5 is a perspective view of a textured structure serving as an example of an embodiment of the present invention.

FIG. 6 is a plan view of the textured structure in FIG. 5, as viewed from above.

FIG. 7 is a perspective view of a textured structure serving as another example of the embodiment of the present invention.

FIG. 8 illustrates a modification of a textured structure in a solar cell serving as an example of an embodiment of the present invention.

FIG. 9 is a plan view of the textured structure in FIG. 8, as viewed from above.

FIG. 10 illustrates a modification of a photoelectric converter in a solar cell serving as an example of an embodiment of the present invention.

FIG. 11 illustrates another modification of a photoelectric converter in a solar cell serving as an example of an embodiment of the present invention.

### DESCRIPTION OF EMBODIMENTS

Detailed descriptions of embodiments of the present invention will be described below with reference to the drawings. However, application of the present invention is not limited to the embodiments. The drawings which are referred to in the embodiments are schematic views. The specific sizes or ratios of components illustrated in the drawings may be different from real ones. Such specific sizes, ratios, etc. should be determined in consideration of the following descriptions.

Unless otherwise noted, the expression “a second member (e.g., transparent conductive layer) is formed on a first member (e.g., photoelectric converter)” herein does not mean only a case where the first member is in direct contact with the second member. That is, the expression includes a case where another element is present between the first and second members.

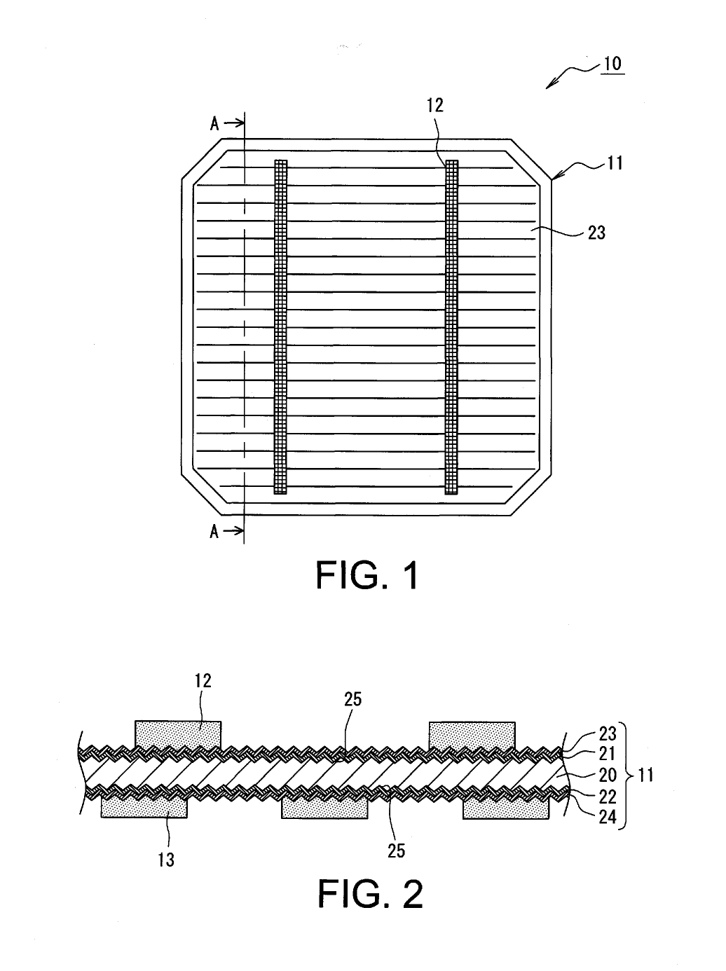

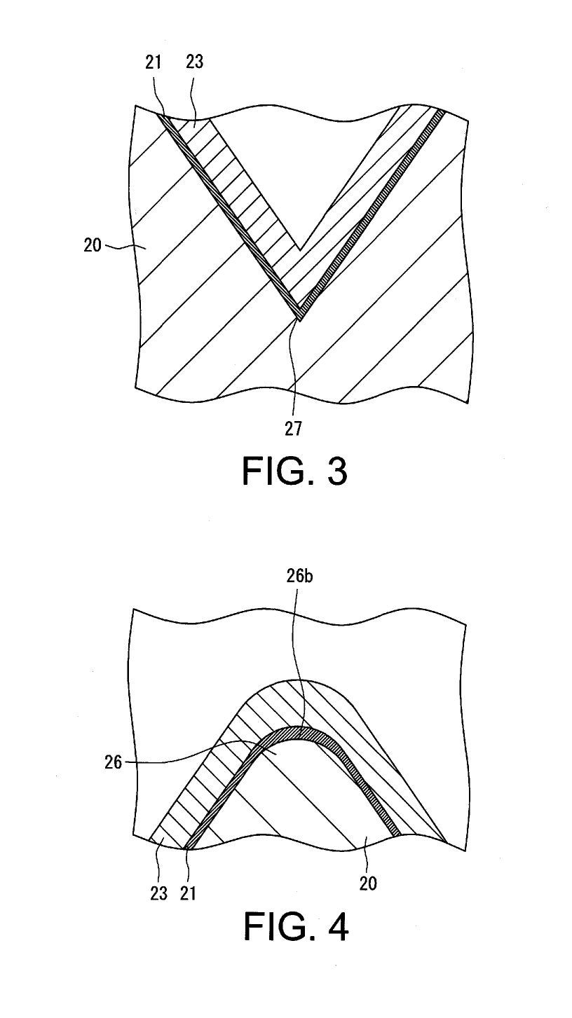

FIG. 1 is a plan view of a solar cell 10 serving as an example of the embodiment, as viewed from a light-receiving surface side. FIG. 2, which is a partial sectional view taken along line A-A in FIG. 1, illustrates a cross section of the solar cell 10 cut in a thickness direction along a direction orthogonal to finger portions of a first electrode 12 and a second electrode 13.

The solar cell 10 includes a photoelectric converter 11 that generates carriers upon reception of solar light, the first electrode 12, which is a light-receiving electrode formed on a light-receiving surface of the photoelectric converter 11, and the second electrode 13, which is a rear electrode formed on a rear face of the photoelectric converter 11. In the solar cell 10, carriers generated by the photoelectric converter 11 are collected by the first electrode 12 and the second electrode 13.

The “light-receiving surface” means a surface to which light mainly enters from the outside of the solar cell 10. For example, above 50% to 100% of light entering the solar cell 10 enters from the light-receiving surface side. The “rear surface” means a surface opposite the light-receiving surface. Hereinafter, the light-receiving surface and the rear surface are collectively referred to as “main surface.”

The photoelectric converter 11 includes a semiconductor substrate 20 (hereinafter referred to as “substrate 20”). The photoelectric converter 11 preferably has an amorphous semiconductor layer 21 on the light-receiving surface side of the substrate 20 and an amorphous semiconductor layer 22 on the rear surface side of the substrate 20. Further, preferably, a transparent conductive layer 23 is formed on the amorphous semiconductor layer 21, and a transparent conductive layer 24 on the amorphous semiconductor layer 22.

The substrate 20 is made of a semiconductor material, such as crystalline silicon (c-Si), or polysilicon (Poly-Si). Of such semiconductor materials, single-crystal silicon is preferable, and n-type single-crystal silicon is particularly preferable. A textured structure 25 that is an uneven surface structure is formed on the substrate 20. The textured structure 25 may be formed only on the light-receiving surface of the substrate 20. Preferably, however, the textured structure 25 is formed on both the light-receiving surface and the rear surface. Details of the textured structure 25 will be given later.

The amorphous semiconductor layer 21 has, for example, a multilayer structure in which an i-type amorphous silicon layer and a p-type amorphous silicon layer are formed in this order from the substrate 20 side. The amorphous semiconductor layer 22 has, for example, a multilayer structure in which an i-type amorphous silicon layer and an n-type amorphous silicon layer are formed in this order from the substrate 20 side. The amorphous semiconductor layers 21 and 22 are formed on the respective textured structures 25. The photoelectric converter 11 may have a structure in which an i-type amorphous silicon layer and an n-type amorphous silicon layer are formed in this order on the light-receiving surface of the substrate 20, and an i-type amorphous silicon layer and a p-type amorphous silicon layer are formed in this order on the rear surface of the substrate 20. The respective amorphous semiconductor layers 21 and 22 preferably have a thickness of approximately 1 to 20 nm, and particularly preferably approximately 5 to 15 nm.

The amorphous semiconductor layers 21 and 22 may be formed by chemical vapor deposition (CVD) or sputtering. To form an i-type amorphous silicon layer by CVD, raw material gas obtained, for example, by diluting silane (SiH₄) with hydrogen (H₂), is used. To form a p-type amorphous silicon layer, there may be used raw material gas obtained by adding diborane (B₂H₆) to silane and diluting the resultant mixture with hydrogen (H₂). To form an n-type amorphous silicon layer, there may be used raw material gas obtained by adding phosphine (PH₃) to silane and diluting the resultant mixture with hydrogen (H₂). The transparent conductive layers 23 and 24 may also be formed by CVD or sputtering.

The transparent conductive layers 23 and 24 may be formed of a transparent conductive oxide that is obtained by doping metal oxide, such as indium oxide (In₂O₃) or zinc oxide (ZnO), with, e.g., tin (Sn) or antimony (Sb). The transparent conductive layers 23 and 24 are formed on the respective textured structures 25 via the amorphous semiconductor layers 21 and 22, respectively. The transparent conductive layers 23 and 24 are formed on regions other than edges on the amorphous semiconductor layers, from the viewpoint of productivity. The respective transparent conductive layers 23 and 24 preferably have a thickness of approximately 30 to 200 nm, and particularly preferably approximately 40 to 100 nm.

The first electrode 12 is a metal electrode that collects carriers via the transparent conductive layer 23. The first electrode 12 includes multiple (for example, 50) finger parts which are filled in trough parts 27 of the textured structure 25 and formed on the transparent conductive layer 23, and multiple (for example, two) bus bar parts which extend in a direction intersecting with the finger parts. The finger parts are thin-line shaped electrodes which are formed over a wide range on the transparent conductive layer 23. The bus bar parts are electrodes that collect carriers from the finger parts. For example, to the bus bar part, which is thicker than the finger part, a wiring material is connected at the time of modularization of the solar cell 10.

The first electrode 12 has a configuration in which conductive fillers, such as silver (Ag), are dispersed in a binder resin, or a configuration including metal only, such as nickel (Ni), copper (Cu), or silver (Ag). For example, the former is formed by screen printing with conductive paste, while the latter is formed by electrolytic plating. The first electrode 12 fills in trough parts 27 of the textured structure 25 (see FIG. 3, which will be described below). The first electrode 12 is formed on the textured structure 25 via e.g., the transparent conductive layer 23.

The second electrode 13, similar to the first electrode 12, preferably includes multiple finger parts which are filled in the trough parts 27 of the textured structure 25 and formed on the transparent conductive layer 24, and multiple bus bar parts which extend to intersect with the finger parts. However, the second electrode 13 preferably has a larger area than the first electrode 12, and the number of the finger parts of the second electrode 13 (for example, 250 finger parts) is, for example, larger than that of the first electrode 12. The second electrode 13 may be a metal layer formed on substantially the entire region on the transparent conductive layer 24.

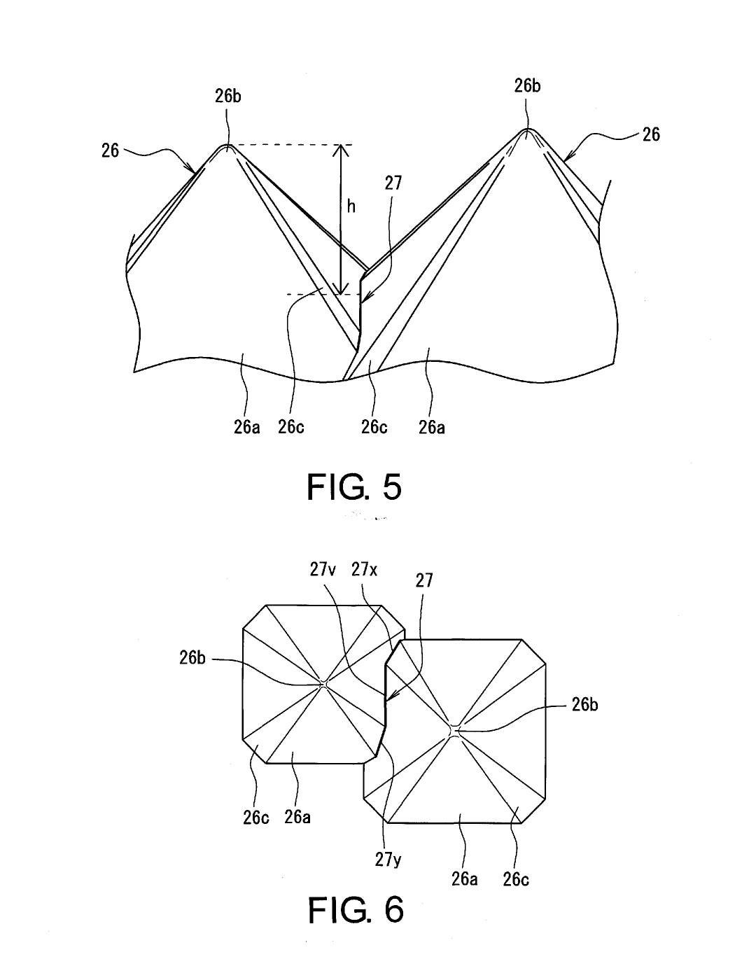

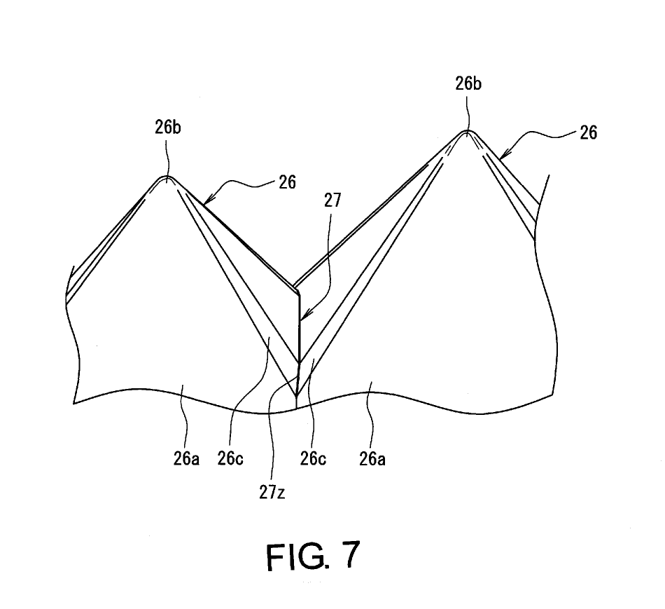

FIGS. 3 to 6 illustrate in an enlarged manner the textured structure 25 on the light-receiving surface side. FIG. 3 is a cross sectional view of the trough part 27. FIG. 4 is a cross sectional view of a front end 26b. FIGS. 5 and 6 illustrate a first example of the textured structure 25. FIG. 7 illustrates a second example of the textured structure 25. The structure of the light-receiving surface side is exemplified herein. The structure of the rear surface side is similar to that of the light-receiving surface side.

The textured structure 25 has an uneven surface structure serving to prevent light from being reflected by a surface and to increase a light absorption amount of the photoelectric converter 11. The structure includes many substantially pyramid shaped convex parts 26. Two adjacent convex parts 26 are in contact with each other. Some of the convex parts 26 may have such a distorted shape that cannot look like a pyramid shape. However, at least half of the convex parts 26 have a substantially pyramid shape which includes four main sloped surfaces 26a that are flat slopes with an area decreasing toward an upper end and includes the front end 26b at the upper end.

The textured structure 25 has a size (hereinafter, may be referred to as “Tx size”) of approximately 1 to 15 μm, preferably approximately 1.5 to 5 μm. The “Tx size”, which means a size when a main surface of the substrate 20 is viewed in plane, can be measured with a scanning electron microscope (SEM) or a laser microscope. Although the Tx size is not limitedly defined, the Tx size is defined, in the following description, as one of sides of the convex part 26 when each convex part 26 on the textured structure 25 is assumed to be a square shape when the main surface of the substrate 20 is viewed in plane. The Tx size means a median which is obtained by measuring approximately 200 convex parts 26.

The height h of the convex part 26 (see FIG. 5) is, for example, 1 to 10 μm, and preferably, 1.5 to 5 μm. The amorphous semiconductor layer 21 and the transparent conductive layer 23 each have a thickness of approximately several nm to several hundred nm. Thus, the textured structure 25 also appears on thin-film layers of the amorphous semiconductor layer 21 and the transparent conductive layer 23. In other words, the amorphous semiconductor layer 21 and the transparent conductive layer 23 are formed depending on the shape of the textured structure 25. The height h of the convex part 26 means a length from a front end 26b, which is the highest portion of the convex part 26, to the trough part 27, which is the deepest portion of the surrounding trough part 27, in a thickness direction of the substrate 20. That is, the height h is a depth of the trough part 27.

In the textured structure 25, the trough parts 27, which are concave parts sandwiched by the adjacent multiple convex parts 26, are sharp (see FIG. 3). That is, the flat main sloped surfaces 26a of adjacent convex parts 26 are directly connected with each other to form the trough part 27. The trough part 27 includes no flat portion along a surface direction of the main surface (a direction orthogonal to the thickness direction of the substrate 20). The textured structure 25 of the trough part 27 has an extremely small curvature radius (hereinafter, referred to as “curvature radius r₂₆”), which is, for example, less than 10 nm. The V-shaped sharp trough part 27 allows incident light to be efficiently reflected multiple times at the trough part 27 to improve the light absorption efficiency of the photoelectric converter 11.

More than half of the convex parts 26 have not the sharp pointed front ends 26b but the rounded front ends 26b (see FIG. 4). That is, a sectional shape of the front end 26b is substantially an arc. The textured structure 25 of the front end 26b has a curvature radius (hereinafter, referred to as “curvature radius r₂₇”) larger than the curvature radius r₂₆, of 50 to 500 nm, for example. The curvature radius r₂₇ is preferably more than five times, more preferably more than ten times, and particularly preferably more than 50 times larger than the curvature radius r₂₆. The rounded front end 26b can prevent the front end 26b from being damaged when the solar cell 10 is manufactured or used.

More than half of the convex parts 26 have chamfered sections 26c between the respective main sloped surfaces 26a. That is, the convex part 26 has a shape with chamfered sides of the pyramid on a boundary of the two adjacent sloped surfaces 26a. For example, four chamfered sections 26c are formed on the single convex part 26. The chamfered section 26c is a flat surface or a gently curved surface like the main sloped surface 26a. The width of the chamfered section 26c preferably decreases toward the front end 26b.

The chamfered section 26c faces, for example, an intermediate direction between a direction to face one of the main sloped surfaces 26a on both sides of the chamfered section 26c and a direction to face the other main sloped surface 26a. The chamfered section 26c has an area smaller than the main sloped surface 26a; for example, less than 10% that of the main sloped surface 26a.

In an example illustrated in FIG. 5, in the trough part 27, the chamfered section 26c is connected to the main sloped surface 26a between the adjacent multiple convex parts 26. That is, the trough part 27 includes a part formed by connection of the respective main sloped surfaces 26a of the adjacent convex parts 26 and a part formed by connection of the main sloped surface 26a of one of the convex parts 26 and the chamfered section 26c of the other convex part 26.

FIG. 6 is a plan view of the trough part 27 in FIG. 5, as viewed from above. As illustrated in FIG. 6, the trough part 27 is bent between the two adjacent convex parts 26. The bent trough part 27 is shaped by the chamfered section 26c. The trough part 27 formed by connection of the main sloped surfaces 26a (referred to as trough part 27v) is a straight line extending in one direction. The chamfered section 26c faces a direction different from that in which the main sloped surface 26a faces. Accordingly, the linear trough part 27v is bent to a direction intersecting with the one direction at a point of the chamfered section 26c. In the example illustrated in FIG. 6, the trough part 27v is bent to a left side by the chamfered section 26c of the left convex part 26 in the drawing, and bent to a right side by the chamfered section 26c of the right convex part 26 in the drawing. In this way, trough parts 27x and 27y are formed, and the length of the trough part 27v extending in the one direction becomes short.

In the example illustrated in FIG. 7, in the trough part 27, the respective chamfered sections 26c of the adjacent convex parts 26 are connected with each other. That is, the trough part 27 has a part formed by connection of the chamfered sections 26c. The textured structure 25 usually includes, at a portion between the adjacent convex parts 26, the trough part 27 formed by connection of the respective main sloped surfaces 26a (the trough part 27v in FIG. 6), the trough part 27 formed by connection of the main sloped surface 26a and the chamfered section 26c (the trough parts 27x, 27y in FIG. 6), and a trough part 27z formed by connection of the respective chamfered sections 26c.

The textured structure 25 may be formed by etching the substrate 20 with etching liquid. When the substrate 20 is a single-crystal silicon substrate with a (100) plane, examples of a preferred type of etching liquid include an alkaline solution, e.g., a solution of sodium hydroxide (NaOH), and a solution of potassium hydroxide (KOH). The concentration of such alkaline solution is preferably 1 to 10 wt. %, approximately. A solvent, which is an aqueous solvent containing water as a main component, includes an additive in an amount of approximately 1 to 10 wt. %, for example. Examples of the additive include an alcohol solvent, e.g., isopropyl alcohol, cyclohexanediol, and octanol, and an organic acid, e.g., 4-propylbenzoic acid, 4-t-butylbenzoic acid, 4-n-butylbenzoic acid, 4-pentylbenzoic acid, 4-butoxybenzonic acid, 4-n-octylbenzenesulfonic acid, caprylic acid, and lauric acid.

If the single-crystal silicon substrate with the (100) plane is immersed in an alkaline solution, anisotropic etching is performed along a (111) plane so that many convex parts having substantially pyramid shapes are formed on the main surface of the substrate 20. The Tx size can be adjusted by changing the substrate 20 to be used, the concentration or the temperature of the etching liquid, the composition ratio, the processing time period or the like. The textured structure 25 may be formed with use of etching gas.

A cleaning process of the substrate 20 may be executed after formation of the textured structure 25. The cleaning process is preferably executed without use of chemical liquid causing further etching of the substrate 20. In the conventional way, for example, a processing process of the substrate 20 is executed with use of a mixed solution (fluonitric acid) of hydrofluoric acid (HF) and nitric acid (HNO₃), after etching of the substrate 20 with use of an alkaline solution. In the manufacturing process of the solar cell 10, no fluonitric acid is used.

In this way, the solar cell 10 includes the sharp trough part 27 sandwiched by the adjacent multiple convex parts 26 and the chamfered section 26c between the respective main sloped surfaces 26a of the convex parts 26. This allows improvement of the light absorption efficiency of the photoelectric converter 11 and increase in resistance to damage of the substrate 20 even when the trough part 27 is sharp. The convex parts 26 and the substrate 20 having the convex parts 26 may be damaged by an impact thereto during manufacture or use of the solar cell 10. The chamfered section 26c can prevent such damage. The chamfered section 26c, for example, can prevent cracking of the edge of the convex part 26. Further, the sharper trough part 27 increases the possibility of cracking of the substrate 20 along the trough part 27. However, the trough part 27 is bent by the chamfered section 26c to have a zigzag shape so that an impact is hardly transmitted along the trough part 27. Thus, cracking of the trough part 27 along the trough part 27 can be prevented.

The chamfered section 26c improves the resistance to damage of the substrate 20. The Tx size also affects the resistance to damage of the substrate 20. More specifically, as the Tx size is smaller, the substrate 20 is less likely to be cracked, thereby improving the resistance to damage. The cracking of the substrate 20 easily occurs along the trough part 27. However, as the Tx size is smaller, an amount of stress on the trough part 27 when a load is added on the main surface of the substrate 20 is smaller. This provides good resistance to damage for the substrate 20 including the textured structure 25 with the small Tx size. To achieve both damage resistance and productivity of the substrate 20, the particularly preferable Tx size is approximately 1 to 5 μm.

The solar cell 10 allows improvement of a photoelectric conversion efficiency by the sharp trough parts 27 and increased probability of the chamfered sections 26c eliminating a problem of the sharp trough parts 27.

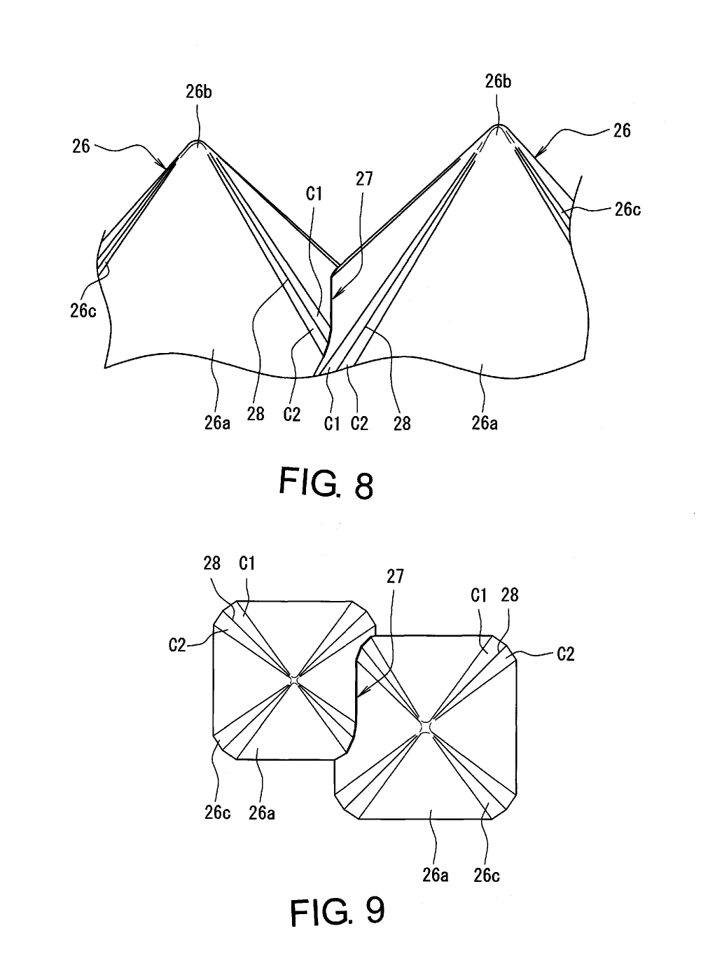

The design of the aforementioned embodiment can be changed as appropriate within the scope of the object of the present invention. As illustrated in FIGS. 8 and 9, a ridgeline 28 may be formed on the chamfered section 26c. The single ridgeline 28 is preferably formed on the single chamfered section 26c in a longitudinal direction of the chamfered section 26c. More than half of the chamfered sections 26c, for example, have the respective ridgelines 28. The ridgeline 28 is formed linearly from the upper part to the lower part of the chamfered section 26c. The textured structure 25 may include both of the chamfered sections 26c with the ridgelines 28 and the chamfered sections 26c with no ridgeline 28 (the embodiment illustrated in FIG. 5). Substantially all of the chamfered sections 26c may have the respective ridgelines 28. The ridgeline 28 can be formed, for example, by anisotropic etching of the substrate 20 which is performed with use of an alkaline solution, such as a solution of sodium hydroxide (NaOH) or a solution of potassium hydroxide (KOH) with the concentration of 0.2% to 8% (mol/L or w/v %) and isopropyl alcohol.

The ridgeline 28 is formed at a center part in a width direction (short-length direction) of the chamfered section 26c. Parts C1 and C2 of the chamfered section 26c, which are divided by the ridgeline 28, have substantially the same areas. The expression “substantially the same” means being the same practically. More specifically, the difference in area between the part C1 and the part C2 is less than 10%, preferably less than 5%. In the embodiment including the ridgeline 28, particularly in the embodiment including substantially the same areas of the parts C1 and C2, a shape of the boundary between the main sloped surface 26a and the chamfered section 26c is gentler and a degree of an angularity is smaller than those in the embodiment including no ridgeline 28. Thus, the ridgeline 28 can further prevent damage to the edge of the convex part 26, for example. In the embodiment including the ridgeline 28, a degree of bending of the trough part 27 by the chamfered section 26c also becomes gentler. Thus, cracking of the substrate 20 along the trough part 27 can be further prevented.

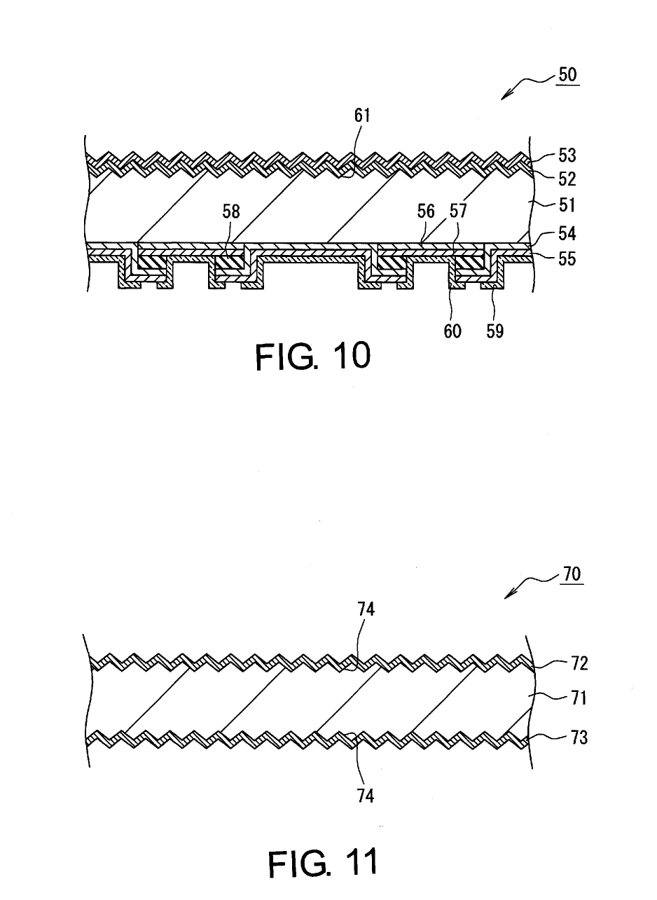

A photoelectric converter other than the photoelectric converter 11 may be applied. As illustrated in FIG. 10, a photoelectric converter 50 may be applied in which on a light-receiving surface side of an n-type single-crystal silicon substrate 51, an i-type amorphous silicon layer 52 and an n-type amorphous silicon layer 53 are formed in this order, while on a rear surface side of the substrate 51, a p-type region formed of an i-type amorphous silicon layer 54 and a p-type amorphous silicon layer 55 and an n-type region formed of an i-type amorphous silicon layer 56 and an n-type amorphous silicon layer 57 are formed. In the photoelectric converter 50, an insulating layer 58 is formed between the p-type region and the n-type region, and transparent conductive layers 59 and 60 are formed on the p-type region and the n-type region, respectively. In the embodiment illustrated in FIG. 10, a textured structure 61 is formed only on a light-receiving surface of the substrate 51. However, a textured structure may be formed on the rear surface of the substrate 51. Further, as illustrated in FIG. 11, a photoelectric converter 70 may be applied which includes a p-type single-crystal silicon substrate 71, an n-type diffusion layer 72 formed on a light-receiving surface side of the substrate 71, and a metal layer 73 formed of, e.g., aluminum, formed on a rear surface of the substrate 71. In the embodiment illustrated in FIG. 11, respective textured structures 74 are formed on the light-receiving surface and the rear surface of the substrate 71.

1. A method for manufacturing a solar cell, the method comprising:
forming a textured structure including multiple convex parts by etching a crystalline silicon substrate with etching liquid in which, to an alkaline solution including at least one of a solution of sodium hydroxide and a solution of potassium hydroxide, additive including at least one of 4-propylbenzoic acid, 4-t-butylbenzoic acid, 4-n-butylbenzoic acid, 4-pentylbenzoic acid, 4-butoxybenzonic acid, 4-n-octylbenzenesulfonic acid, caprylic acid, and lauric acid is added, the textured structure having a chamfered section between main sloped surfaces of the convex parts, and a sharp trough part which is sandwiched by adjacent multiple convex parts; and
forming an amorphous silicon layer on the crystalline silicon substrate with the textured structure formed thereon, by chemical vapor deposition or sputtering.

2. The method according to claim 1, further comprising
cleaning the crystalline silicon substrate after said forming of the textured structure,
wherein said forming of the amorphous silicon layer is performed after said cleaning of the crystalline silicon substrate.

3. The method according to claim 1, further comprising
after said forming of the amorphous silicon layer, forming a transparent conductive layer containing any one of indium oxide and zinc oxide on the textured structure having the amorphous silicon layer formed thereon.

4. The method according to claim 3, further comprising
after said forming of the transparent conductive layer, forming a metal electrode including a plurality of thin-line shaped finger parts on the textured structure having the transparent conductive layer formed thereon,
wherein the metal electrode is formed on the transparent conductive layer so as to fill the trough part of the textured structure having the transparent conductive layer formed thereon.

5. The method according to claim 4, wherein the metal electrode contains any one of nickel, copper, and silver.

6. The method according to claim 5, wherein
the metal electrode is formed of a conductive paste containing a binder resin, and
said forming of the metal electrode is carried out by screen printing.

7. The method according to claim 5, wherein
said forming of the textured structure comprises forming the textured structure on a light-receiving surface side and a rear surface side of the crystalline silicon substrate;
said forming of the amorphous silicon layer comprises forming the amorphous silicon layer on the light-receiving surface side and the rear surface side of the crystalline silicon substrate;
said forming of the transparent conductive layer comprises forming the transparent conductive layer on the light-receiving surface side and the rear surface side of the crystalline silicon substrate;
the metal electrode comprises a first electrode formed on the light-receiving surface side of the crystalline silicon substrate and a second electrode formed on the rear surface side of the crystalline silicon substrate; and
said forming of the metal electrode comprises forming the first electrode including the finger parts on the light-receiving surface side of the crystalline silicon substrate, and forming the second electrode on the rear surface side of the crystalline silicon substrate so that the second electrode has a larger area than the first electrode.
